(19) United States
(12) Patent Application Publication
(10) Pub. No.: US 2025/0343152 A1
(43) Pub. Date: Nov. 6, 2025

(54) SEMICONDUCTOR DEVICE STRUCTURE AND METHOD OF FORMATION

(71) Applicant: Taiwan Semiconductor Manufacturing Company, Ltd., Hsinchu (TW)

(72) Inventors: Chih-Chang Cheng, Hsinchu City (TW); Po-Chih Su, New Taipei City (TW); Ruey-Hsin Liu, Hsin-Chu (TW); Ming-Ta Lei, Hsin-Chu City (TW)

(21) Appl. No.: 19/269,125

(22) Filed: Jul. 15, 2025

Related U.S. Application Data
(62) Division of application No. 17/570,710, filed on Jan. 7, 2022.
(60) Provisional application No. 63/224,889, filed on Jul. 23, 2021.
(60) Provisional application No. 63/230,980, filed on Aug. 9, 2021.

(51) Int. Cl. H01L 23/538; H01L 23/00; H01L 25/065

(52) U.S. Cl. CPC H01L 23/5384; H01L 23/5386; H01L 23/5389; H01L 24/14; H01L 25/0652

(57) ABSTRACT

The present disclosure relates an integrated chip structure. The integrated chip structure includes a first chiplet predominantly having a first plurality of integrated chip devices coupled to a first plurality of interconnects over a first substrate. The first plurality of integrated chip devices are a first type of integrated chip device. The integrated chip structure further includes a second chiplet predominantly having a second plurality of integrated chip devices coupled to a second plurality of interconnects over a second substrate. The second plurality of integrated chip devices are a second type of integrated chip device different than the first type of integrated chip device. One or more inter-chiplet connectors are between the first and second chiplets and are configured to electrically couple the first and second chiplets. The first plurality of interconnects have a first minimum width different than a second minimum width of the second plurality of interconnects.

### REFERENCE TO RELATED APPLICATIONS

This Application is a Divisional of U.S. application Ser. No. 17/570,710, filed on Jan. 7, 2022, which claims the benefit of U.S. Provisional Application No. 63/224,889, filed on Jul. 23, 2021 & U.S. Provisional Application No. 63/230,980, filed on Aug. 9, 2021. The contents of the above-referenced Patent Applications are hereby incorporated by reference in their entirety.

### BACKGROUND

The integrated chip fabrication industry has often used scaling to develop new products (e.g., new chips). Scaling is the process by which a minimum feature size on an integrated chip is reduced or made smaller. By reducing the minimum feature size on an integrated chip, the performance of individual devices on the integrated chip (e.g., the power consumption, speed, etc.) can be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional view of some embodiments of an integrated chip structure comprising one or more chiplets respectively predominantly having a single type of integrated chip device.

FIG. 2 illustrates a cross-sectional view of some embodiments of an integrated chip structure comprising a plurality of chiplets respectively predominantly having a single type of integrated chip device.

FIG. 3 illustrates a cross-sectional view of some additional embodiments of an integrated chip structure comprising a plurality of chiplets respectively predominantly having a single type of device with a single type of contact etch stop layer strain.

FIG. 4 illustrates a cross-sectional view of some additional embodiments of an integrated chip structure comprising a plurality of chiplets respectively predominantly having a single type of device with a single type of sidewall spacer strain.

FIG. 5 illustrates a cross-sectional view of some additional embodiments of an integrated chip structure comprising a plurality of chiplets respectively predominantly having a single type of device with a single type of source/drain material.

FIG. 6 illustrates a cross-sectional view of some additional embodiments of an integrated chip structure comprising a plurality of chiplets respectively predominantly having a single type of device with a single type of transistor structure.

FIG. 7 illustrates a cross-sectional view of some additional embodiments of an integrated chip structure comprising a plurality of chiplets respectively predominantly having a single type of device with a single channel direction.

FIG. 8 illustrates a cross-sectional view of some embodiments of an integrated chip structure comprising a plurality of chiplets respectively predominantly having a single type of transistor device and one or more passive devices.

FIGS. 9A-9B illustrate some embodiments of a power management circuit having different components associated with different chiplets.

FIGS. 10A-10B illustrate some alternative embodiments of a power management circuit having different components associated with different chiplets.

FIG. 11 illustrates a cross-sectional view of some embodiments of a packaged integrated chip structure comprising a plurality of chiplets respectively predominantly having a single type of integrated chip device.

FIGS. 12A-16C illustrate cross-sectional views showing some embodiments of a method of forming an integrated chip structure comprising a plurality of chiplets respectively predominantly having a single type of integrated chip device.

FIG. 17 illustrates a flow diagram of some embodiments of a method of forming an integrated chip structure comprising a plurality of chiplets respectively predominantly having a single type of integrated chip device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For decades, the semiconductor industry has made integrated circuits (ICs) faster and more power efficient by reducing the size of features (e.g., gate lengths, interconnect widths, etc.) on the ICs. Reducing the size of features on an IC is generally known as semiconductor scaling. Within the industry, different fabrication processes (e.g., technology nodes or process nodes) are used to generate integrated chips having devices with different minimum feature sizes. For example, a transistor gate length in a 28 nanometer (nm) technology node is generally smaller than a transistor gate length in a 45 nm technology node. Generally, a smaller technology node has smaller transistors, which are both faster and more power-efficient.

In more recent years, as scaling has become more difficult, other fabrication processes (e.g., using different strains and/or materials on an integrated chip) have also been used to enhance device performance. Because not all device types benefit equally from scaling and/or from other fabrication process enhancements, an overall performance of an IC is usually optimized by trying to balance a fabrication process to meet the needs of a plurality of different device types (e.g., NMOS transistors, PMOS transistors, passive devices, etc.). However, because different device types are optimized by different fabrication processes a resulting IC may have an overall sub-optimal performance. For example, a fabrication process that forms NMOS transistors and PMOS transistors on a single chip may optimize the operation of one type of device (e.g., NMOS transistors), without optimizing the performance of another type of device (e.g., PMOS transistors). Therefore, such fabrication process balancing sacrifices an optimal performance of one or more device types within an integrated chip.

The present disclosure, in some embodiments, relates to an integrated chip structure that is configured to optimize a performance of different device types within the integrated chip structure. The integrated chip structure comprises a plurality of chiplets formed by way of a different fabrication processes. The plurality of chiplets are coupled together by way of one or more inter-chiplet interconnects. Respective ones of the plurality of chiplets predominately comprise a single type of device that is different than that of the other chiplets. For example, the integrated chip structure may comprise a first chiplet predominately comprising PMOS transistors formed by way of a first fabrication process (e.g., a 65 nm technology node process) and a second chiplet predominately comprising NMOS transistors formed by way of a second fabrication process (e.g., a 45 nm technology node process). By forming the different types of devices using different fabrication processes, the different types of devices can respectively be formed using a fabrication process that optimizes the performance of each of the types of devices, thereby mitigating the negative effects (e.g., degrading integrated chip performance) of fabrication process balancing between different device types.

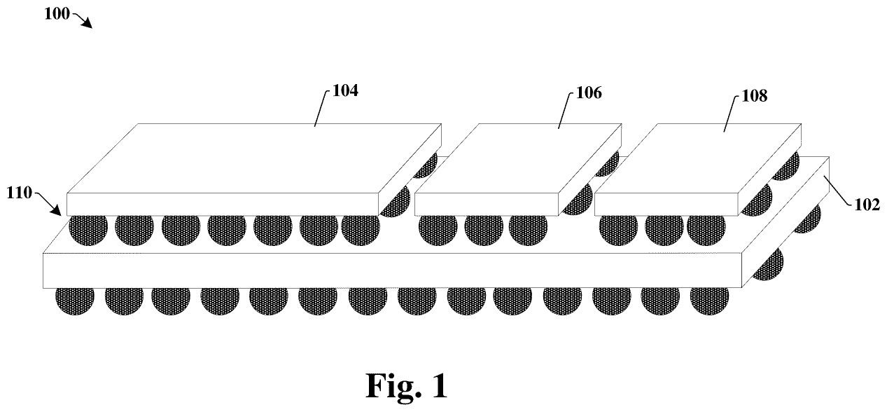

FIG. 1 illustrates a three-dimensional view of some embodiments of an integrated chip structure 100 comprising a plurality of chiplets respectively predominantly having a single type of integrated chip device.

The integrated chip structure 100 comprises a plurality of chiplets 102-108. In some embodiments, the plurality of chiplets 102-108 may comprise a first chiplet 102, a second chiplet 104, a third chiplet 106, and a fourth chiplet 108. One or more of the plurality of chiplets 102-108 predominately comprise a single type of integrated chip device (e.g., comprise more than 80% of a single type of integrated chip device, comprise more than 90% of a single type of integrated chip device, comprise more than 95% of a single type of integrated chip device, comprise more than 99% of a single type of integrated chip device, comprise approximately 100% of a single type of integrated chip device, comprise only a single type of integrated chip device). In some embodiments, a single type of integrated chip device may be a single type of transistor device. In other embodiments, a single type of integrated chip device may be a passive device (e.g., a capacitor, a resistor, an inductor, or the like), a gate driver circuit, or the like.

For example, in some embodiments, the first chiplet 102 may predominantly comprise a first plurality of integrated chip devices that are a first type of integrated chip device (e.g., an NMOS transistor) and the second chiplet 104 may predominantly comprise a second plurality of integrated chip devices that are a second type of integrated chip device (e.g., a PMOS transistor). In some embodiments, the first chiplet 102 may predominately comprise the first type of integrated chip device and be devoid of the second type of device. In some embodiments, the first chiplet 102 may only comprise the first type of integrated chip device.

In some embodiments, the plurality of chiplets 102-108 may respectively comprise a single type of integrated chip device, wherein the single type of integrated chip device on each of the plurality of chiplets 102-108 is formed by a different fabrication process. For example, in some embodiments the first chiplet 102 may predominately comprise NMOS devices formed by a first fabrication process that optimizes performance of the NMOS devices, the second chiplet 104 may predominately comprise PMOS devices formed by a second fabrication process that optimizes performance of the PMOS devices, the third chiplet 106 may predominately comprise passive devices (e.g., inductors, capacitors, resistors, or the like) formed by a third fabrication process that optimizes performance of the passive devices, and the fourth chiplet 108 may predominately comprise transistor devices defining one or more gate driver circuits formed by a fourth fabrication process that optimizes performance of the one or more gate driver circuits. In some embodiments, the different fabrication processes may be different technology node processes. For example, in some embodiments, the first fabrication process may comprise a first technology node process (e.g., a 7 nm technology node process), the second fabrication process may comprise a second technology node process (e.g., a 14 nm technology node process), the third fabrication process may comprise a third technology node process (e.g., a 65 nm technology node process), and the fourth fabrication process may comprise a fourth technology node process (e.g., a 45 nm technology node process). In some alternative embodiments, the first technology node process may be the same as the second technology node process. In some alternative embodiments, the third technology node process may be the same as the fourth technology node process. In additional embodiments, the different fabrication processes may provide IC devices within each of the plurality of chiplets 102-108 with different materials, different strains, different channel directions, or the like.

The different types of integrated chip devices within the plurality of chiplets 102-108 are coupled together by way of one or more inter-chiplet connectors 110. The one or more inter-chiplet connectors 110 are configured to allow the different types of integrated chip devices to operate together to perform a function. In some embodiments, the one or more inter-chiplet connectors 110 may comprise one or more of redistribution layers (RDLs), copper posts, conductive bumps (e.g., micro-bumps), a solder joint, a copper to copper joint, a copper to aluminum copper joint, an aluminum copper to an aluminum copper joint, a through-substrate-via (TSV) joint, or the like. In some embodiments, the plurality of chiplets 102-108 may be stacked onto one another in a multi-dimensional chip structure (e.g., three-dimensional integrated chip (3DIC) structure). For example, in some embodiments, the second chiplet 104, the third chiplet 106, and the fourth chiplet 108 may be stacked onto an upper surface of the first chiplet 102. In such embodiments, the first chiplet 102 may have larger area than the second chiplet 104, the third chiplet 106, and the fourth chiplet 108.

By having the plurality of chiplets 102-108 respectively and predominately comprise a single type of integrated chip device, the different types of integrated chip devices can be formed using a fabrication process that optimizes the performance of each type of integrated chip device. By forming the different types of integrated chip devices using fabrication processes that optimize the performance of each type of integrated chip device, device degradation due to fabrication process balancing can be avoided and an overall performance of the integrated chip structure can be improved.

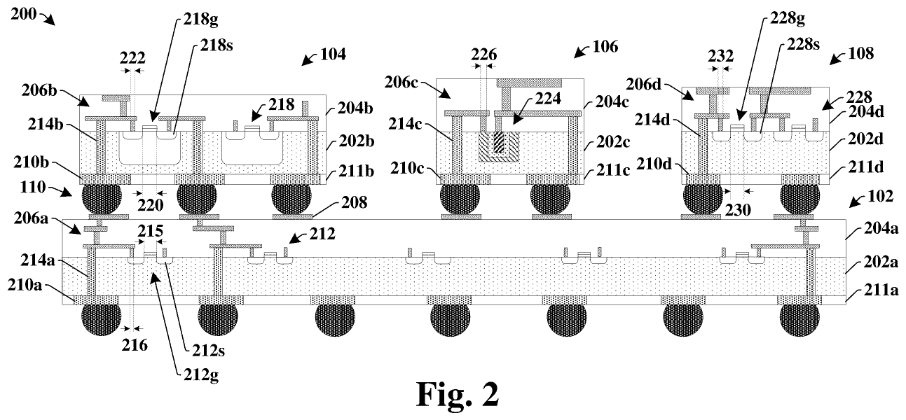

FIG. 2 illustrates a cross-sectional view of some additional embodiments of an integrated chip structure 200 comprising a plurality of chiplets respectively predominantly having a single type of integrated chip device.

The integrated chip structure 200 comprises a plurality of chiplets 102-108 coupled to one another by way of inter-chiplet connectors 110. In some embodiments, the plurality of chiplets 102-108 may comprise a first chiplet 102, a second chiplet 104, a third chiplet 106, and a fourth chiplet 108. The plurality of chiplets 102-108 respectively predominately comprise a different type of integrated chip device.

For example, in some embodiments the first chiplet 102 may predominately comprise a first plurality of transistor devices 212 that are a first type of transistor device. In some additional embodiments the first chiplet 102 may only comprise the first type of transistor device. The first plurality of transistor devices 212 respectively comprise a first gate structure 212g disposed between first source/drain regions 212s. In some embodiments, the first type of transistor device is an NMOS transistor, so that the first plurality of transistor devices 212 are NMOS transistors. In such embodiments, the first source/drain regions 212s may comprise a first doping type (e.g., an n-type doping), while a channel region extending under the first gate structure 212g and between the first source/drain regions 212s may comprise a second doping type (e.g., a p-type doping). In some embodiments, the first gate structure 212g may have a first gate length 215.

In some embodiments, the first chiplet 102 may further comprise a first plurality of interconnects 206a disposed within a first inter-level dielectric (ILD) structure 204a over the first substrate 202a. In some embodiments, the first plurality of interconnects 206a may comprise conductive contacts, interconnect wires, and/or interconnect vias. In some embodiment, the first plurality of interconnects 206a may comprise a first conductive contact disposed on one of the first plurality of transistor devices 212 and having a first contact width 216. In some embodiments, the first plurality of interconnects 206a may be coupled to one or more front-side bonding structures 208 disposed over the first ILD structure 204a. In various embodiments, the one or more front-side bonding structures 208 may comprise a redistribution layer, a bond pad, an under bump metallurgy (UBM) structure, or the like. In some additional embodiments, the first plurality of interconnects 206a may be further coupled to one or more first back-side bonding structures 210a by way of a first through-substrate via (TSV) 214a. The one or more first back-side bonding structures 210a are separated from the first ILD structure 204a by the first substrate 202a. In various embodiments, the first back-side bonding structures 210a may comprise a redistribution layer, a bond pad, a UBM structure, or the like. In some embodiments, the one or more first back-side bonding structures 210a may be disposed on or within a first passivation structure 211a disposed on the first substrate 202a.

In some embodiments, the second chiplet 104 may comprise a second plurality of transistor devices 218 that are a second type of transistor device that is different than the first type of transistor device. In some additional embodiments the second chiplet 104 may only comprise the second type of transistor device. The second plurality of transistor devices 218 respectively comprise a second gate structure 218g disposed between second source/drain regions 218s within a second substrate 202b. In some embodiments, the second type of transistor device is a PMOS transistor so that the second plurality of transistor devices 218 are PMOS transistors. In such embodiments, the second source/drain regions 218s may comprise the second doping type (e.g., the p-type doping), while a channel region extending under the second gate structure 218g and between the second source/drain regions 218s may comprise the first doping type (e.g., the n-type doping). In some embodiments, the second gate structure 218g may comprise a second gate length 220 that is different than (e.g., larger than) the first gate length 215. In some embodiments, a second plurality of interconnects 206b are disposed within a second ILD structure 204b over the second substrate 202b. In some embodiment, the second plurality of interconnects 206b may comprise a conductive contact disposed on one of the second plurality of transistor devices 218 and having a second contact width 222. In some embodiments, the first plurality of interconnects 206a have a first minimum width (e.g., the first contact width 216) that is different than a second minimum width (e.g., the second contact width 222) of the second plurality of interconnects 206b. For example, in some embodiments the second contact width 222 is larger than the first contact width 216. In some embodiments, the second plurality of interconnects 206b may be coupled to one or more second back-side bonding structures 210b that are on and/or within a second passivation structure 211b disposed on a back-side of the second substrate 202b by way of a second TSV 214b.

In some embodiments, the third chiplet 106 may predominately comprise passive devices 224 (e.g., capacitors, inductors, resistors, or the like) on and/or within a third substrate 202c. In some embodiments, the third chiplet 106 may be devoid of transistor devices. For example, the third chiplet 106 may be free of NMOS and PMOS transistor devices. In some additional embodiments the third chiplet 106 may only comprise passive devices 224. In some embodiments, the passive devices 224 may comprise a capacitor having a first electrode separated from a second electrode by way of a capacitor dielectric structure. In other embodiments, the passive devices 224 may comprise an inductor. In yet other embodiments, the passive devices 224 may comprise a resistor. In some embodiments, a third plurality of interconnects 206c are disposed within a third ILD structure 204c over the third substrate 202c. The third plurality of interconnects 206c may comprise a conductive contact disposed on one of the passive devices 224 and having a third contact width 226 that is different than (e.g., larger than) the first contact width 216 and/or the second contact width 222. In some embodiments, the third plurality of interconnects 206c may be coupled to one or more third back-side bonding structures 210c that are on and/or within a third passivation structure 211c disposed on a back-side of the third substrate 202c.

In some embodiments, the fourth chiplet 108 may predominately comprise a third plurality of transistor devices 228 that define one or more gate driver circuits. In some additional embodiments the fourth chiplet 108 may only comprise transistor devices that define one or more gate driver circuits. In some embodiments, the third plurality of transistor devices 228 may comprise a third gate structure 228g between third source/drain regions 228s within a fourth substrate 202d. In some embodiments, the third gate structure 228g may comprise a third gate length 230 that is different than (e.g., larger than) the first gate length 214 and/or the second gate length 220. In some embodiments, a fourth plurality of interconnects 206d are disposed within a fourth ILD structure 204d over the fourth substrate 202d. In some embodiments, the fourth plurality of interconnects 206d may be coupled to one or more fourth back-side bonding structures 210d that are on and/or within a fourth passivation structure 211d disposed on a back-side of the fourth substrate 202d. The fourth plurality of interconnects 206d may comprise a conductive contact disposed on one of the third plurality of transistor devices 228 and having a fourth contact width 232 that is different than (e.g., larger than) the first contact width 216, the second contact width 222, and/or the third contact width 226.

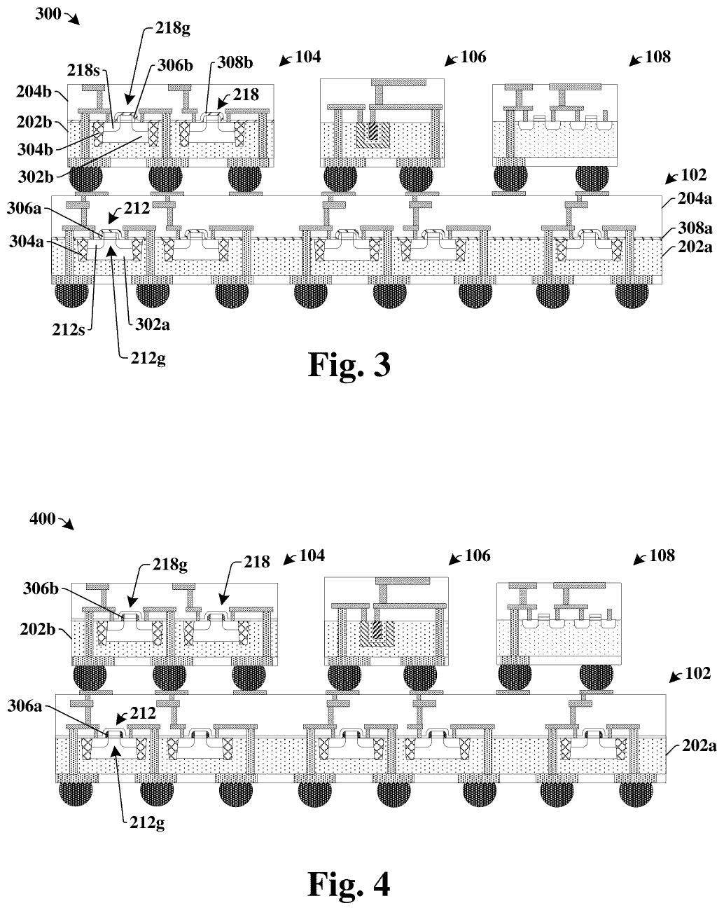

While FIG. 2 illustrates an integrated chip structure 200 comprising different chiplets that respectively have predominately different types of integrated chip devices (e.g., NMOS devices, PMOS devices, etc.), it will be appreciated that in additional embodiments the different types of integrated chip devices within a respective chiplet may predominately have other features and/or additional features. For example, the different integrated chip devices within a same chiplet may predominately have a same strain, gate orientation, material, and/or the like. FIGS. 3-7 illustrate cross-sectional views of some additional embodiments of integrated chip structures comprising a plurality of chiplets respectively predominantly having a single type of integrated chip device with same features.

FIG. 3 illustrates a cross-sectional view of some embodiments of an integrated chip structure 300 comprising a plurality of chiplets respectively predominantly having a single type of device with a single type of contact etch stop layer strain.

The integrated chip structure 300 comprises a plurality of chiplets 102-108. In some embodiments, the plurality of chiplets 102-108 may comprise a first chiplet 102, a second chiplet 104, a third chiplet 106, and a fourth chiplet 108. In some embodiments, the first chiplet 102 may predominately comprise a first plurality of transistor devices 212 (e.g., NMOS transistors), the second chiplet 104 may predominately comprise a second plurality of transistor devices 218 (e.g., PMOS transistors), the third chiplet 106 may predominately comprise one or more passive devices 224, and the fourth chiplet 108 may predominately comprise a third plurality of transistor devices 228 configured to operate as one or more gate driver circuits.

The first plurality of transistor devices 212 may comprise a first gate structure 212g disposed over a first well region 302a disposed within a first substrate 202a. In some embodiments, the first well region 302a may be disposed between one or more first isolation structures 304a respectively comprising one or more dielectric materials disposed within a trench in the first substrate 202a. The first gate structure 212g is disposed over the first substrate 202a between first source/drain regions 212s. One or more first sidewall spacers 306a are arranged along opposing sides of the first gate structure 212g. A first contact etch stop layer (CESL) 308a is disposed over the first substrate 202a and along sides of the first gate structure 212g. A first plurality of interconnects 206a are disposed within a first ILD structure 204a over the first CESL 308a. In some embodiments, the first CESL 308a comprises a first type of strain. In some embodiments, the first type of stress may be a tensile strain.

The second chiplet 104 may comprise a second gate structure 218g disposed over a second well region 302b disposed within a second substrate 202b. The second gate structure 218g is disposed over the second substrate 202b between second source/drain regions 218s. One or more second sidewall spacers 306b are arranged along opposing sides of the second gate structure 218g. A second CESL 308b is disposed over the second substrate 202b and along sides of the second gate structure 218g. A second plurality of interconnects 206b are disposed within a second ILD structure 204b over a second substrate 202b. In some embodiments, the second CESL 308b comprises a second type of strain that is different than the first type of strain. In some embodiments, the second type of strain may comprise a compressive strain.

While NMOS and PMOS transistors are typically formed by a fabrication process that utilizes a same CESL for both NMOS and PMOS transistors, it has been appreciated that a strained CESL affects different types of transistors differently. For example, a CESL having tensile strain may enhance NMOS transistor performance while a CESL having a compressive strain may enhance PMOS transistor performance. Therefore, by forming the first CESL 308a over the first plurality of transistor devices 212 and the second CESL 308b over the second plurality of transistor devices 218, device performance can be optimized for both NMOS and PMOS transistors within a same integrated chip structure.

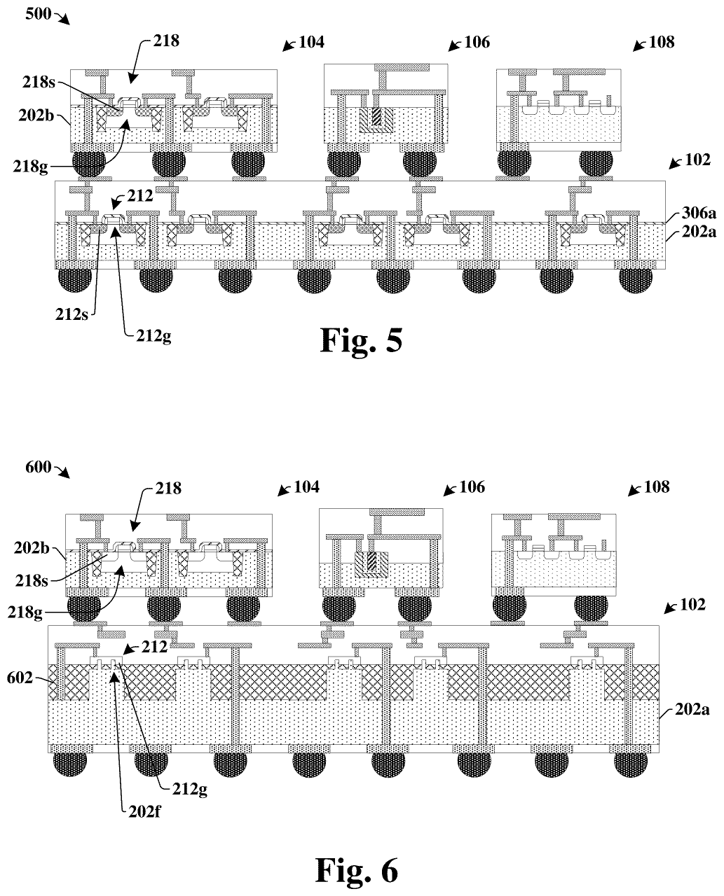

FIG. 4 illustrates a cross-sectional view of some embodiments of an integrated chip structure 400 comprising a plurality of chiplets respectively predominantly having a single type of device with a single type of sidewall spacer strain.

The integrated chip structure 400 comprises a plurality of chiplets 102-108. In some embodiments, the plurality of chiplets 102-108 may comprise a first chiplet predominately comprising a first plurality of transistor devices 212 and a second chiplet 104 predominately comprising a second plurality of transistor devices 218.

The first plurality of transistor devices 212 may comprise a first gate structure 212g disposed on a first substrate 202a. One or more first sidewall spacers 306a are arranged along opposing sides of the first gate structure 212g. In some embodiments, the one or more first sidewall spacers 306a comprise a first type of strain. In some embodiments, the first type of stress may comprise a tensile strain. The second plurality of transistor devices 218 may comprise a second gate structure 218g disposed on a second substrate 202b. One or more second sidewall spacers 306b are arranged along opposing sides of the second gate structure 218g. In some embodiments, the one or more second sidewall spacers 306b comprise a second type of strain that is different than the first type of strain. In some embodiments, the second type of strain may comprise a compressive strain.

While NMOS and PMOS transistors are typically formed by a fabrication process that utilizes a same sidewall spacer strain for both NMOS and PMOS transistors, it has been appreciated that strained sidewall spacers affect different types of transistors differently. For example, a sidewall spacer having tensile strain may enhance NMOS transistor performance while a sidewall spacer having a compressive strain may enhance PMOS transistor performance. Therefore, by forming the one or more first sidewall spacers 306a around the first plurality of transistor devices 212 and the one or more second sidewall spacers 306b around the second plurality of transistor devices 218, device performance can be optimized for both NMOS and PMOS transistors within a same integrated chip structure.

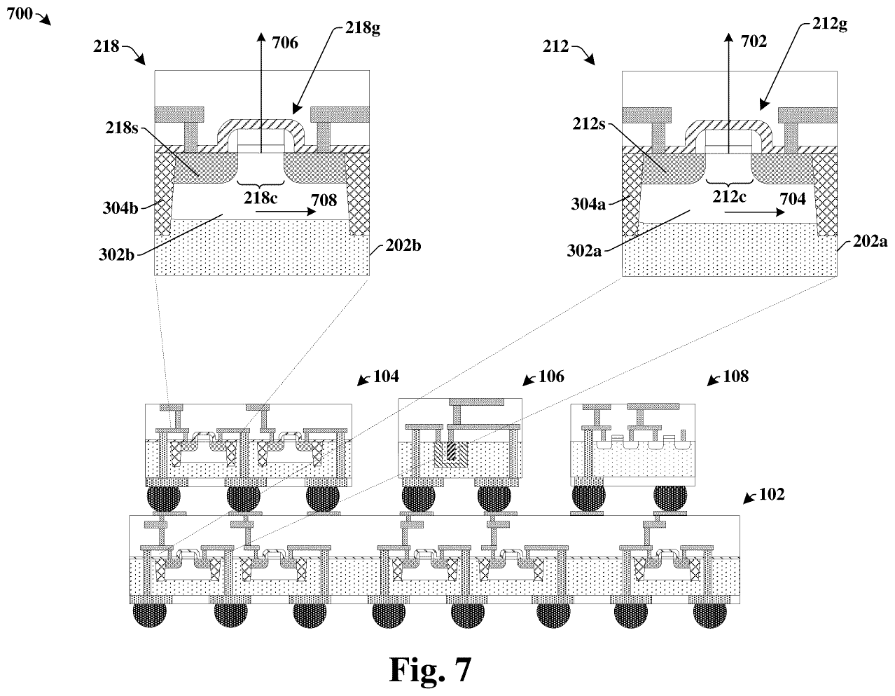

FIG. 5 illustrates a cross-sectional view of some embodiments of an integrated chip structure 500 comprising a plurality of chiplets respectively predominantly having a single type of device with a single type of source/drain strain.

The integrated chip structure 500 comprises a plurality of chiplets 102-108. In some embodiments, the plurality of chiplets 102-108 may comprise a first chiplet predominately comprising a first plurality of transistor devices 212 and a second chiplet 104 predominately comprising a second plurality of transistor devices 218.

The first plurality of transistor devices 212 may comprise a first gate structure 212g disposed over a first substrate 202a between first source/drain regions 212s. In some embodiments, the first source/drain regions 212s may comprise a first type of semiconductor material. For example, the first source/drain regions 212s may comprise silicon carbide. The second plurality of transistor devices 218 may comprise a second gate structure 218g disposed over a second substrate 202b between second source/drain regions 218s. In some embodiments, the second source/drain regions 218s may comprise a second type of semiconductor material that is different than the first type of semiconductor material. For example, the second source/drain regions 218s may comprise silicon germanium.

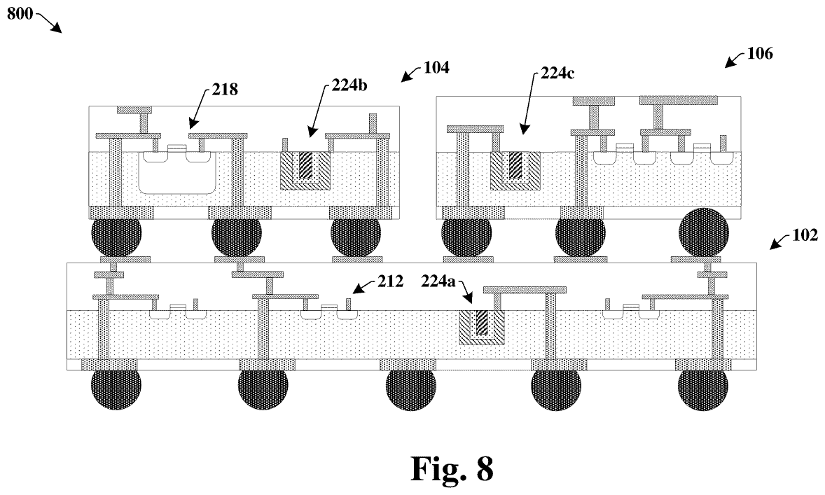

FIG. 6 illustrates a cross-sectional view of some embodiments of an integrated chip structure 600 comprising a plurality of chiplets respectively predominantly having a single type of device with single type of transistor structure.

The integrated chip structure 600 comprises a plurality of chiplets 102-108. In some embodiments, the plurality of chiplets 102-108 may comprise a first chiplet predominately comprising a first plurality of transistor devices 212 and a second chiplet 104 predominately comprising a second plurality of transistor devices 218.

The first plurality of transistor devices 212 may have a first transistor structure. In some embodiments, the first transistor structure may comprise a FinFET structure. In such embodiments, the first substrate 202a comprises one or more fins 202f of semiconductor material extending outward from an upper surface of the first substrate 202a. An isolation structure 602 is arranged along opposing sides of the one or more fins 202f of semiconductor material. A first gate structure 212g wraps around the one or more fins of semiconductor material. Source/drain regions (not shown) are disposed on opposing sides of the fin 202f of semiconductor material, so that a channel region of the plurality of FinFET devices extends into or out of the page. In other embodiments, the first type of transistor structure may comprise a gate all around (GAA) transistor structure, a nano-sheet transistor structure, a planar FET structure, or the like.

The second plurality of transistor devices 218 may have a second transistor structure that is different than the first transistor structure. In some embodiments, the second transistor structure may comprise a planar FET structure. In such embodiments, a plurality of planar transistor devices respectively comprise a second gate structure 218g disposed over an upper surface of the second substrate 202b and between second source/drain regions 218s within the upper surface of the second substrate 202b. In other embodiments, the second type of transistor structure may comprise a FinFET transistor structure, a gate all around (GAA) transistor structure, a nano-sheet transistor structure, or the like.

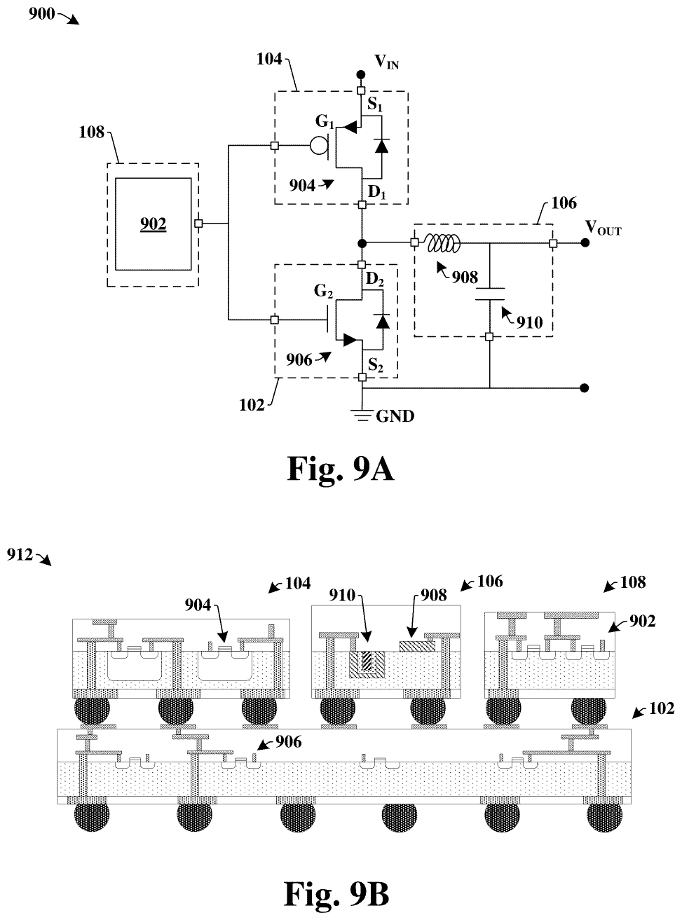

FIG. 7 illustrates a cross-sectional view of some embodiments of an integrated chip structure 700 comprising a plurality of chiplets respectively predominantly having a single type of device with a single channel direction.

The integrated chip structure 700 comprises a plurality of chiplets 102-108. In some embodiments, the plurality of chiplets 102-108 may comprise a first chiplet predominately comprising a first plurality of transistor devices 212 and a second chiplet 104 predominately comprising a second plurality of transistor devices 218.

The first plurality of transistor devices 212 may comprise a first gate structure 212g disposed over a first substrate 202a. The first gate structure 212g is between first source/drain regions 212s. A first channel region 212c is disposed below the first gate structure 212g and between the first source/drain regions 212s. In some embodiments, the upper surface of the first substrate 202a may face a first direction 702 (i.e., a line that is normal to the upper surface of the first substrate 202a may extend in the first direction 702) and the first channel region 212c may extend along a second direction 704. For example, in some embodiments the first direction 702 may be a [100] direction (e.g., a direction that is normal to a (100) crystal plane) and the second direction 704 may be along a (110) crystal plane.

The second plurality of transistor devices 218 may comprise a second gate structure 218g disposed over a second substrate 202b. The second gate structure 218g is between second source/drain regions 218s. A second channel region 218c is disposed below the second gate structure 218g and between the second source/drain regions 218s. In some embodiments, the upper surface of the second substrate 202b may face a third direction 706 (i.e., a line that is normal to the upper surface of the second substrate 202b may extend in the third direction 706) and the second channel region 218c may extend along a fourth direction 708. For example, in some embodiments the third direction 706 may be a [110] direction (e.g., a direction that is normal to a (110) crystal plane) and the fourth direction 708 may be along a (110) crystal plane.

Typically, NMOS and PMOS devices are fabricated on a same wafer. However, it has been appreciated that the majority charge carriers of NMOS and PMOS devices are different and that different majority charge carriers have different mobilities in different directions. For example, electrons have their greatest mobility in the {100} family of crystal planes, while holes have their greatest mobility in the {110} family of crystal planes. Therefore, by forming the first plurality of transistor devices 212 to have a first channel region 212c along a first crystal plane (e.g., along a (100) crystal plane) and the second plurality of transistor devices 218 to have a second channel region 218c along a second crystal plane (e.g., along a (110) crystal plane), transistor device performance can be optimized for both NMOS and PMOS transistors.

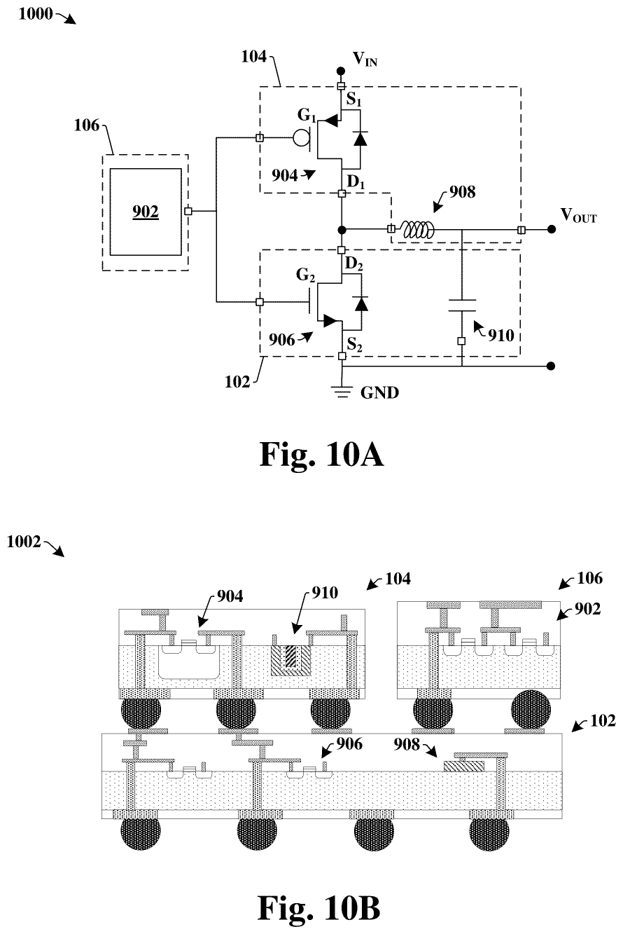

FIG. 8 illustrates an alternative embodiment of an integrated chip structure 800 that has one or more chiplets predominately comprising a single type of transistor device.

The integrated chip structure 800 comprises a first chiplet 102, a second chiplet 104, and a third chiplet 106. The first chiplet 102 comprises a first plurality of transistor devices 212 that are predominately NMOS devices. The second chiplet 104 comprises a second plurality of transistor devices 218 that are predominately PMOS devices. The third chiplet 106 comprises a third plurality of transistor devices 228 that predominantly define one or more gate driver circuits.

In some embodiments, one or more of the first chiplet 102, the second chiplet 104, and the third chiplet 106 may further comprise one or more passive devices. For example, in some embodiments the first chiplet 102 may predominantly comprise the first plurality of transistors devices 212 and one or more first passive devices 224a (e.g., one or more capacitors, inductors, etc.). In some additional embodiments, the second chiplet 104 may predominantly comprise the second plurality of transistors devices 218 and one or more second passive devices 224b (e.g., one or more inductors, capacitors, etc.). In some additional embodiments, the third chiplet 106 may predominantly comprise the third plurality of transistors devices 228 and one or more third passive devices 224c (e.g., one or more resistors, inductors, etc.). Since passive devices may not be affected by some fabrication process enhancements (e.g., different strains and/or materials), the passive devices may be able to be integrated into a chiplet that has a single type of transistor device without having a large impact on a performance of the passive devices.

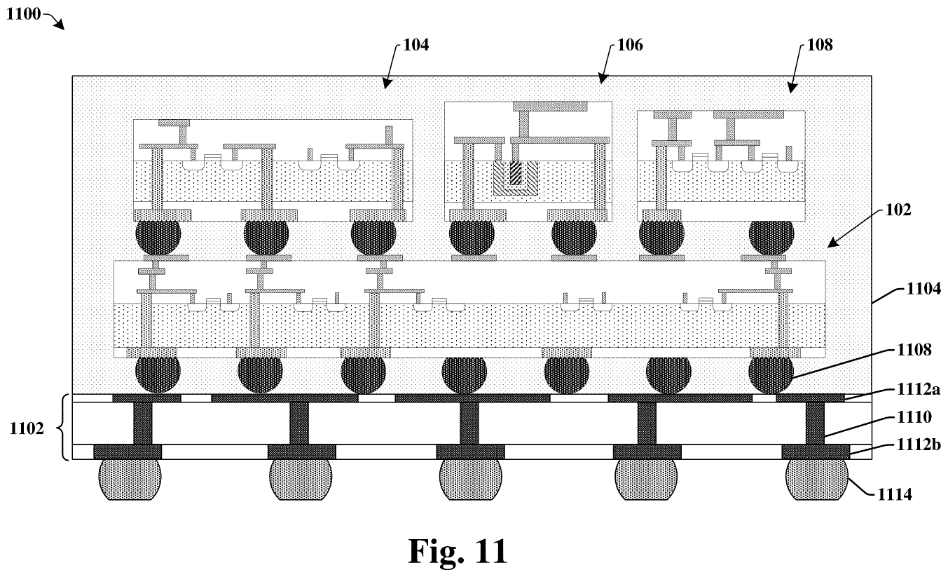

FIG. 9A illustrates some embodiments of an exemplary schematic diagram of a power management circuit 900 having different components associated with different chiplets.

The power management circuit 900 comprises a buck converter having a gate driver circuit 902 coupled to a first gate G₁ of a high side driver 904 and to a second gate G₂ of a low side driver 906. In some embodiments, the high side driver 904 may comprise a PMOS transistor having a first source S₁ coupled to an input voltage (V_{IN}) and the low side driver 906 may comprise an NMOS transistor having a second source S₂ coupled to ground (GND). A first drain D₁ of the high side driver 904 is further coupled to a second drain D₂ of the low side driver 906 at a shared node. The shared node is further coupled to a resonant circuit that is configured to output an output voltage (V_{OUT}). The resonant circuit comprises an inductor 908 and a capacitor 910. During operation, the gate driver circuit 902 is configured to switch the high side driver 904 and the low side driver 906. The resonant circuit is configured to store energy and then dissipate energy to generate the output voltage (V_{OUT}), which has a voltage value that is a reduced from the input voltage (V_{IN}), thereby acting as a DC-to-DC converter.

In some embodiments, the gate driver circuit 902 may be disposed on a fourth chiplet 108, the high side driver 904 may be disposed on a second chiplet 104, the low side driver 906 may be disposed on a first chiplet 102, and the resonant circuit may be disposed on a third chiplet 106. FIG. 9B illustrates a cross-sectional view 912 of some embodiments of an integrated chip structure comprising chiplets respectively comprising components of the buck converter circuit of FIG. 9A.

Buck converters are typically formed on a single substrate using a same process with same materials. However, by forming each of the buck converter circuit components on a different chiplet, a performance of the buck converter circuit may be improved by optimizing the devices within each of the converter components. For example, in some embodiments, the buck converter circuit may be disposed within a power management integrated circuit (PMIC) of a smartphone and be configured to receive an input voltage V_{IN}, having a value in a range of between approximately 3.7 V (volts) and approximately 5 V, from a battery and to output the output voltage (V_{OUT}), having a value in a range of between approximately 3.7 V and approximately 5 V, to an application processor (AP). In some such embodiments, the buck converter circuit may be configured to operate at a frequency of between approximately 100 KHz (kilohertz) and approximately 10 MHz (megahertz) and to output a current that is in a range of between approximately 0.5 A (Amperes) and approximately 3 A.

In other embodiments, the buck converter circuit may be disposed within a PMIC of a server and be configured to receive an input voltage V_{IN}, having a value in a range of between approximately 5 V and approximately 12 V, from a motherboard and to output the output voltage (V_{OUT}), having a value in a range of between approximately 0.6 V and approximately 1.2 V, to a central processing unit (CPU). In some such embodiments, the buck converter circuit may be configured to operate at a frequency of between approximately 100 KHz and approximately 10 MHz and to output a current that is in a range of between approximately 20 A and approximately 100 A.

In yet embodiments, the buck converter circuit may be disposed within smartphone wireless charging system and be configured to receive an input voltage V_{IN}, having a value in a range of between approximately 12 V and approximately 20 V, from a wireless charging plate receiving end and to output the output voltage (V_{OUT}), having a value in a range of between approximately 3.7 V and approximately 5 V, to a battery. In some such embodiments, the buck converter circuit may be configured to operate at a frequency of between approximately 205 KHz and approximately 6.78 MHz and to output a current that is in a range of between approximately 0.5 A and approximately 3 A.

In yet other embodiments, other types of circuits may also be formed with components that are disposed on different chiplets. For example, in some additional embodiments the power management circuit may comprise a boost converter circuit having components disposed on different chiplets. By having the components of the boost converter disposed on different chiplets, the boost converter may be able to achieve a good performance. For example, in some embodiments a disclosed booster converter circuit may be disposed within a PMIC of a smartphone and be configured to receive an input voltage V_{IN}, having a value in a range of between approximately 3.7 V (volts) and approximately 5 V, from a battery and to output the output voltage (V_{OUT}), having a value in a range of between approximately 6 V and approximately 32 V), to a display circuit. In some such embodiments, the booster converter may be configured to operate at a frequency of between approximately 10 KHz and approximately 100 KHz.

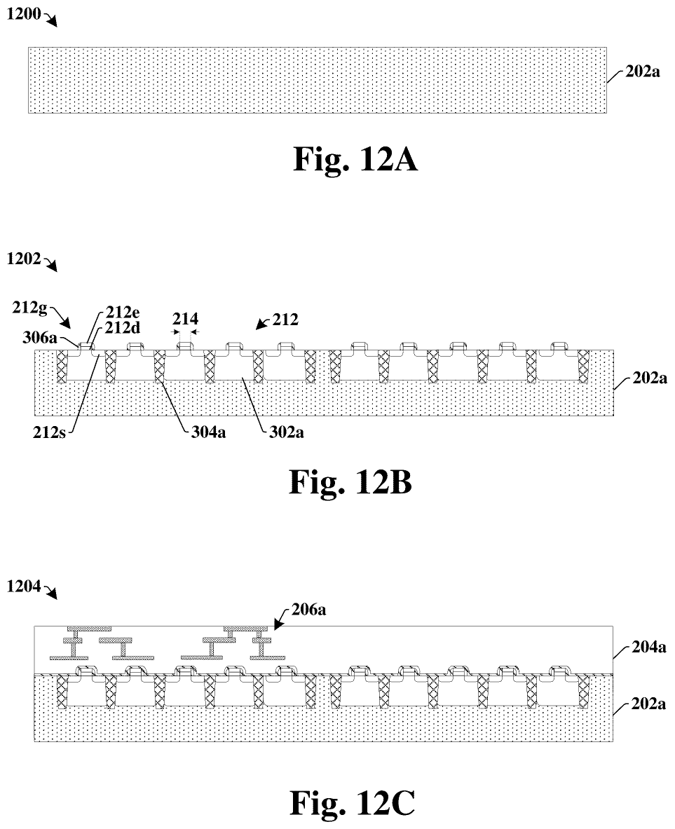

FIG. 10A illustrates some alternative embodiments of an exemplary schematic diagram of a power management circuit 1000 having different components associated with different chiplets.

The power management circuit 1000 comprises a buck converter comprising a gate driver circuit 902 coupled to a first gate G₁ of a high side driver 904 and to a second gate G₂ of a low side driver 906. A resonant circuit is coupled to a first drain D₁ of the high side driver 904 and a second drain D₂ of the low side driver 906. The resonant circuit comprises an inductor 908 and a capacitor 910.

In some embodiments, the gate driver circuit 902 may be disposed on a fourth chiplet 108, the high side driver 904 may be disposed on a second chiplet 104, the low side driver 906 may be disposed on a first chiplet 102, and the inductor 908 and the capacitor 910 may be disposed on one of the first chiplet 102, the second chiplet 104, and the third chiplet 106. For example, FIG. 10B illustrates a cross-sectional view 1002 of some embodiments of an integrated chip structure comprising a first chiplet having an NMOS transistor of the high side driver 904 and an inductor 908 of the resonant circuit, a second chiplet having a PMOS transistor of the low side driver and a capacitor 910 of the resonant circuit, and a third chiplet 106 having a gate driver circuit 902.

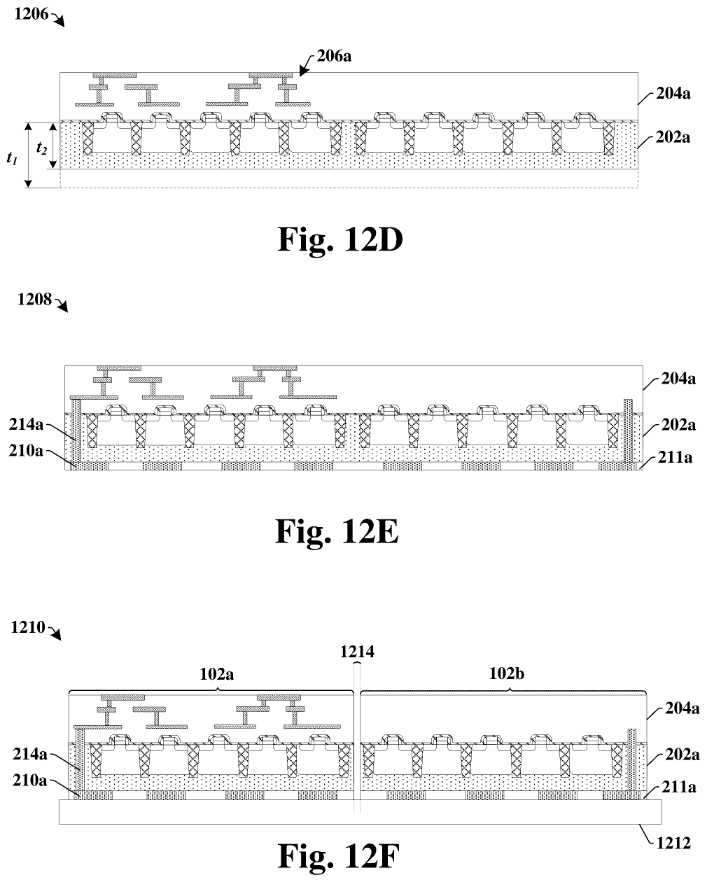

It will be appreciated that the disclosed integrated chip structure may be packaged in a variety of package types. FIG. 11 illustrates a cross-sectional view of some embodiments of an integrated chip structure 1100 comprising a plurality of chiplets packaged in a CoWoS (chip-on-wafer-on-substrate) package.

The packaged integrated chip structure 1100 comprises a plurality of chiplets 102-108 disposed over a carrier substrate 1102 (e.g., an interposer substrate). The plurality of chiplets 102-108 respectively predominantly have a single type of integrated chip device. In some embodiments, a molding compound 1104 is also disposed over the carrier substrate 1102 and surrounds the plurality of chiplets 102-108.

The plurality of chiplets 102-108 are electrically coupled to the carrier substrate 1102 by way of a plurality of micro-bumps 1108. A plurality of through substrate vias (TSVs) 1110 extend through the carrier substrate 1102 and electrically couple the plurality of micro-bumps 1108 to a plurality of solder bumps 1114. In some embodiments, one or more redistribution layers, 1112a and/or 1112b, may be arranged along top and/or bottoms of the carrier substrate 1102 to provide for lateral routing between the TSVs 1110 and the plurality of micro-bumps 1108 and/or the plurality of solder bumps 1114.

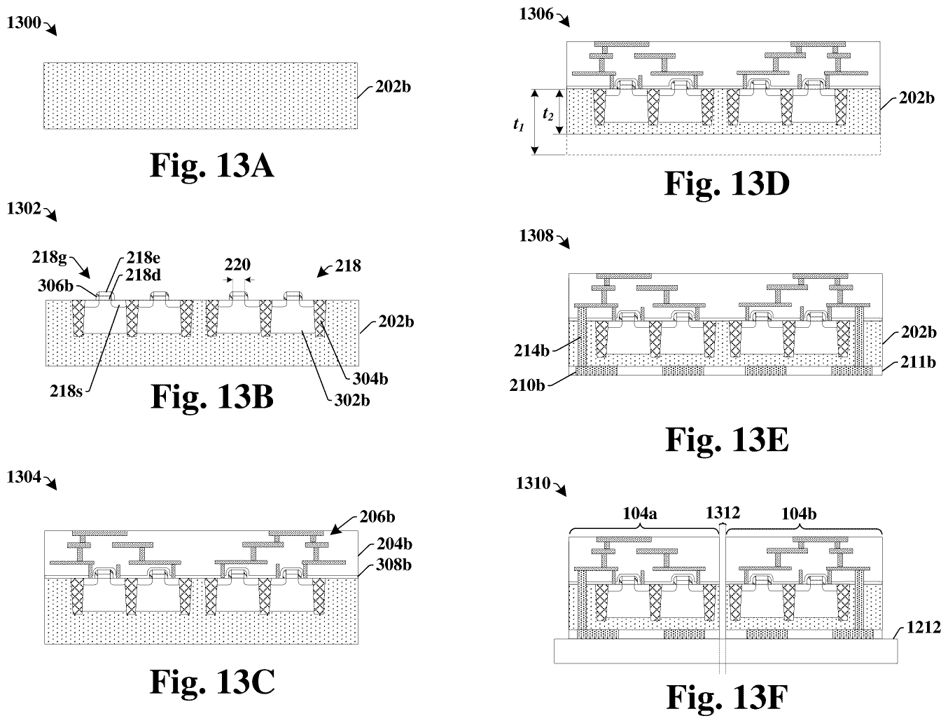

FIGS. 12A-16C illustrate cross-sectional views 1200-1604 showing some embodiments of a method of forming an integrated chip structure comprising a plurality of chiplets respectively predominantly having a single type of integrated chip device. Although FIGS. 12A-16C are described in relation to a method, it will be appreciated that the structures disclosed in FIGS. 12A-16C are not limited to such a method, but instead may stand alone as structures independent of the method.

As shown in cross-sectional view 1200 of FIG. 12A, a first substrate 202a is provided. In various embodiments, the first substrate 202a may be any type of semiconductor body (e.g., silicon, SiGe, SOI, etc.), such as a semiconductor wafer and/or one or more die on a wafer, as well as any other type of semiconductor and/or epitaxial layers, associated therewith.

As shown in cross-sectional view 1202 of FIG. 12B, a first plurality of transistor devices 212 are formed within the first substrate 202a. A majority of the devices within the first substrate 202a are the first plurality of transistor devices 212. In some embodiments, the first plurality of transistor devices 212 may be respectively formed by forming a first gate structure 212g over the first substrate 202a. In some embodiments, the first gate structure 212g may be formed by depositing a first gate dielectric film and a first gate electrode film over the first substrate 202a. The first gate dielectric film and the first gate electrode film are subsequently patterned to form a first gate dielectric 212d and a first gate electrode 212e. In some embodiments, the first gate structure 212g may be formed to have a first gate length 214. First source/drain regions 212s are formed along opposing sides of the first gate structure 212g. In some embodiments, one or more first sidewall spacers 306a may be formed along opposing sides of the first gate structure 212g. In some embodiments, the one or more first sidewall spacers 306a may be formed to have a first type of strain (e.g., tensile strain).

In some embodiments, the first plurality of transistor devices 212 may comprise an NMOS transistor. In some such embodiments, a first well region 302a may be implanted into the first substrate 202a prior to the formation of the first gate structure 212g over the first substrate 202a. In some embodiments, the first well region 302a may be formed by a first implantation process that implants dopants (e.g., boron, aluminum, etc.) having a second doping type (e.g., p-type) into the first substrate 202a. In some embodiments, a second implantation process may subsequently be performed to implant dopants (e.g., phosphorous, arsenic, antimony, etc.) having a first doping type (e.g., n-type) into the first well region 302a. In some alternative embodiments, the first plurality of transistor devices 212 may comprise epitaxial source/drain regions having a first semiconductor material formed within the first substrate 202a. In some embodiments, the first semiconductor material may comprise silicon carbide.

As shown in cross-sectional view 1204 of FIG. 12C, a first CESL 308a is formed on the first substrate 202a and over the first plurality of transistor devices 212. The first CESL 308a may comprise a nitride (e.g., silicon nitride), a carbide (e.g., silicon carbide), or the like. In some embodiments, the first CESL 308a may have a first type of strain (e.g., tensile strain). A first plurality of interconnects 206a may be formed within a first ILD structure 204a formed on the first CESL 308a. In some embodiments, the first plurality of interconnects 206a may respectively be formed using a damascene process (e.g., a single damascene process or a dual damascene process). The damascene process is performed by forming an ILD layer on the first substrate 202a, etching the ILD layer to form a via hole and/or a trench, and filling the via hole and/or the trench with a conductive material. In some embodiments, the ILD layer may be deposited by a deposition process (e.g., a physical vapor deposition (PVD) process, a chemical vapor deposition (CVD) process, a plasma enhanced chemical vapor deposition (PE-CVD) process, an atomic layer deposition (ALD) process, etc.) and the conductive material (e.g., tungsten, copper, aluminum, or the like) may be formed using a deposition process and/or a plating process (e.g., electroplating, electro-less plating, etc.).

As shown in cross-sectional view 1206 of FIG. 12D, the first substrate 202a may be thinned to reduce a thickness of the first substrate 202a. In various embodiments, the first substrate 202a may be thinned by etching and/or mechanical grinding a back-side of the first substrate 202a to reduce the thickness of the first substrate 202a from a first thickness t₁ to a second thickness t₂. In some embodiments, the first thickness t₁ may be in a range of between approximately 700 μm and approximately 800 μm. In some embodiments, the second thickness t₂ may be in a range of between approximately 20 μm and approximately 80 μm.

As shown in cross-sectional view 1208 of FIG. 12E, a first TSV 214a is formed to extend through the first substrate 202a. In some embodiments, the first TSV 214a may be formed by performing a first etching process to pattern the first substrate 202a and form sidewalls of the first substrate 202a that extend through the first substrate 202a and that define a first TSV opening. In some embodiments, the first TSV opening extends through the first CESL 308a and the first ILD structure 204a to expose one of the first plurality of interconnects 206a. A conductive material is formed within the TSV opening. The conductive material may be formed by way of a deposition process and/or a plating process (e.g., electroplating, electro-less plating, etc.). In various embodiments, the conductive material may comprise copper, aluminum, or the like. After forming the conductive material within the TSV opening, a planarization process may be performed to remove excess of the conductive material and to define a first TSV 214a extending through the first substrate 202a.

A first back-side bonding structure 210a is formed along a back-side of the first substrate 202a. The first back-side bonding structure 210a may be formed on and/or within a first passivation structure 211a formed along the back-side of the first substrate 202a.

As shown in cross-sectional view 1210 of FIG. 12F, the first substrate 202a is singulated to form a plurality of first chiplets 102a-102b. In some embodiments, the first substrate 202a may be singulated by a dicing process that mounts the first substrate 202a onto a sticky surface of a piece of dicing tape 1212. A wafer saw then cuts the first substrate 202a along scribe lines 1214 to separate the first substrate 202a into the plurality of first chiplets 102-102b.

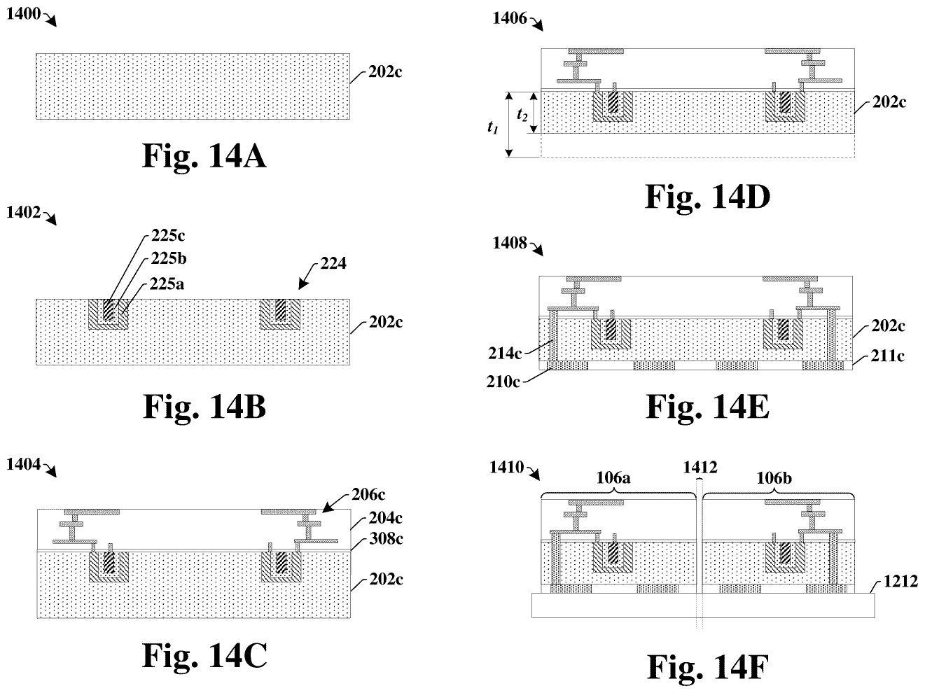

As shown in cross-sectional view 1300 of FIG. 13A, a second substrate 202b is provided. In various embodiments, the second substrate 202b may be any type of semiconductor body (e.g., silicon, SiGe, SOI, etc.), such as a semiconductor wafer and/or one or more die on a wafer, as well as any other type of semiconductor and/or epitaxial layers, associated therewith.

As shown in cross-sectional view 1302 of FIG. 13B, a second plurality of transistor devices 218 are formed within the second substrate 202b. The second plurality of transistor devices 218 may comprise a majority of the devices within the second substrate 202b. In some embodiments, the second plurality of transistor devices 218 may be respectively formed by forming a second gate structure 218g over the second substrate 202b. In some embodiments, the second gate structure 218g may be formed by depositing a second gate dielectric film and a second gate electrode film over the second substrate 202b. The second gate dielectric film and the second gate electrode film are subsequently patterned to form a second gate dielectric 218d and a second gate electrode 218e. In some embodiments, the second gate structure 218g may be formed to have a second gate length 220 that is different than (e.g., larger than) the first gate length 214. Second source/drain regions 218s are formed along opposing sides of the second gate structure 218g. In some embodiments, the second source/drain regions 218s may comprise epitaxial source/drain regions having a second semiconductor material formed within the second substrate 202b. In some embodiments, the second semiconductor material may comprise silicon germanium. In some embodiments, one or more second sidewall spacers 306b may be formed along opposing sides of the second gate structure 218g. In some embodiments, the one or more second sidewall spacers 306b may be formed to have a second type of strain (e.g., compressive strain) that is different than the first type of strain of the one or more first sidewall spacers (306a of FIG. 12B).

In some embodiments, the first plurality of transistor devices 212 may comprise a PMOS transistor. In some such embodiments, a second well region 302b may be implanted into the second substrate 202b between one or more second isolation structures 304b prior to the formation of the second gate structure 218g over the second substrate 202b. In some embodiments, the second well region 302b may be formed by a first implantation process that implants dopants (e.g., phosphorous, arsenic, antimony, etc.) having a first doping type (e.g., n-type) into the second substrate 202b. In some embodiments, a second implantation process may subsequently be performed to implant dopants (e.g., boron, aluminum, etc.) having a second doping type (e.g., p-type) into the second well region 302b. In some alternative embodiments, the second plurality of transistor devices 218 may comprise epitaxial source/drain regions having a second semiconductor material formed within the second substrate 202b. In some embodiments, the second semiconductor material may comprise silicon germanium.

It has been appreciated that forming NMOS devices on the first substrate (e.g., 202a of FIG. 12B) and PMOS devices on the second substrate 202b, that a power consumption and/or performance of the NMOS and PMOS devices may be improved. Furthermore, a cost and cycle time of the fabrication processes may also be improved since the fabrication processes used to form the NMOS devices and PMOS devices may be streamlined. For example, forming NMOS and PMOS devices on a same substrate may require more masks to be used than forming NMOS and PMOS devices on separate substrates.

As shown in cross-sectional view 1304 of FIG. 13C, a second CESL 308b is formed on the second substrate 202b and over the second plurality of transistor devices 218. The second contact etch stop layer 308b may comprise a nitride (e.g., silicon nitride), a carbide (e.g., silicon carbide), or the like. In some embodiments, the second CESL 308b may have a second type of strain (e.g., compressive strain) that is different than the first type of strain of the first CESL (308a of FIG. 12C). A second plurality of interconnects 206b may be formed within a second ILD structure 204b formed on the second CESL 308b.

As shown in cross-sectional view 1306 of FIG. 13D, the second substrate 202b may be thinned to reduce a thickness of the second substrate 202b. In various embodiments, the second substrate 202b may be thinned by etching and/or mechanical grinding a back-side of the second substrate 202b to reduce the thickness of the second substrate 202b (e.g., from a first thickness t₁ in a range of between approximately 700 μm and approximately 800 μm to a second thickness t₂ in a range of between approximately 20 μm and approximately 80 μm).

As shown in cross-sectional view 1308 of FIG. 13E, a second TSV 214b is formed to extend through the second substrate 202b. A second back-side bonding structure 210b is formed along a back-side of the second substrate 202b. The second back-side bonding structure 210b may be formed on and/or within a second passivation structure 211b formed along the back-side of the second substrate 202b.

As shown in cross-sectional view 1310 of FIG. 13F, the second substrate 202b is singulated to form a plurality of second chiplets 104a-104b. In some embodiments, the second substrate 202b may be singulated by a dicing process that mounts the second substrate 202b onto a sticky surface of a piece of dicing tape 1212. A wafer saw then cuts the second substrate 202b along scribe lines 1312 to separate the second substrate 202b into the plurality of second chiplets 104a-104b.

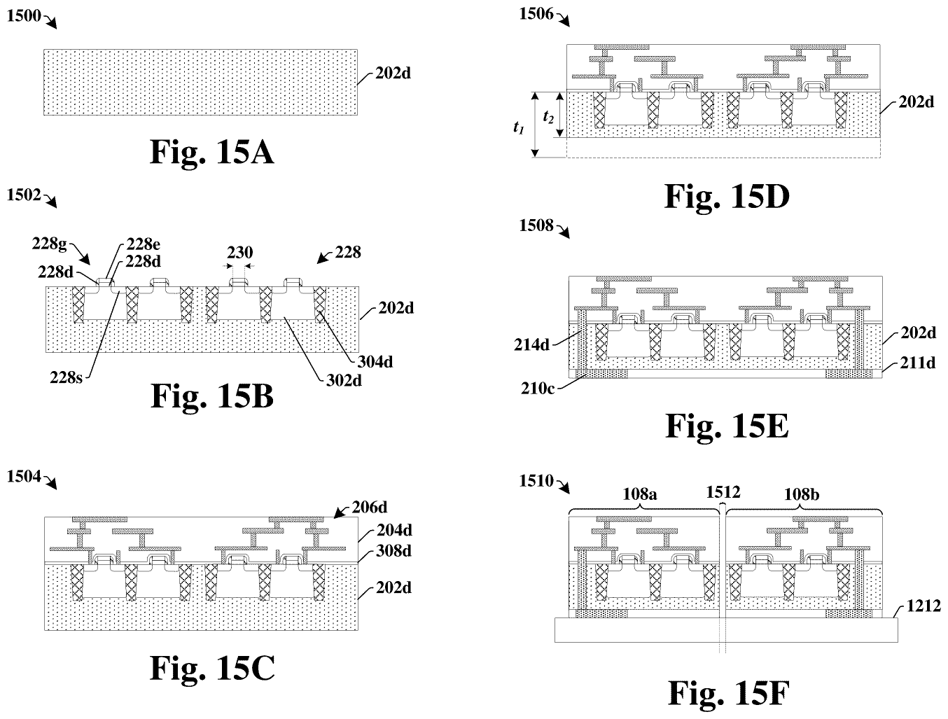

As shown in cross-sectional view 1400 of FIG. 14A, a third substrate 202c is provided. In various embodiments, the third substrate 202c may be any type of semiconductor body (e.g., silicon, SiGe, SOI, etc.), such as a semiconductor wafer and/or one or more die on a wafer, as well as any other type of semiconductor and/or epitaxial layers, associated therewith.

As shown in cross-sectional view 1402 of FIG. 14B, a plurality of passive devices 224 are formed on and/or within the third substrate 202c. In some embodiments, the plurality of passive devices 224 may comprise a capacitor having a first conductive layer 225a separated from a second conductive layer 225c by way of a capacitor dielectric layer 225b. In other embodiments, the plurality of passive devices 224 may comprise inductors, resistors, or the like.

As shown in cross-sectional view 1404 of FIG. 14C, a third CESL 308c is formed on the third substrate 202c. A third plurality of interconnects 206c may be formed within a third ILD structure 204c formed on the third CESL 308c.

As shown in cross-sectional view 1406 of FIG. 14D, the third substrate 202c may be thinned to reduce a thickness of the third substrate 202c. In various embodiments, the third substrate 202c may be thinned by etching and/or mechanical grinding a back-side of the third substrate 202c to reduce the thickness of the third substrate 202c (e.g., from a first thickness t₁ in a range of between approximately 700 μm and approximately 800 μm to a second thickness t₂ in a range of between approximately 20 μm and approximately 80 μm).

As shown in cross-sectional view 1408 of FIG. 14E, a third TSV 214c is formed to extend through the third substrate 202c. A third back-side bonding structure 210c is formed along a back-side of the third substrate 202c. The third back-side bonding structure 210c may be formed on and/or within a third passivation structure 211c formed along the back-side of the third substrate 202c.

As shown in cross-sectional view 1410 of FIG. 14F, the third substrate 202c is singulated to form a plurality of third chiplets 106a-106b. In some embodiments, the third substrate 202c may be singulated by a dicing process that mounts the third substrate 202c onto a sticky surface of a piece of dicing tape 1212. A wafer saw then cuts the third substrate 202c along scribe lines 1412 to separate the third substrate 202c into the plurality of third chiplets 106a-106b.

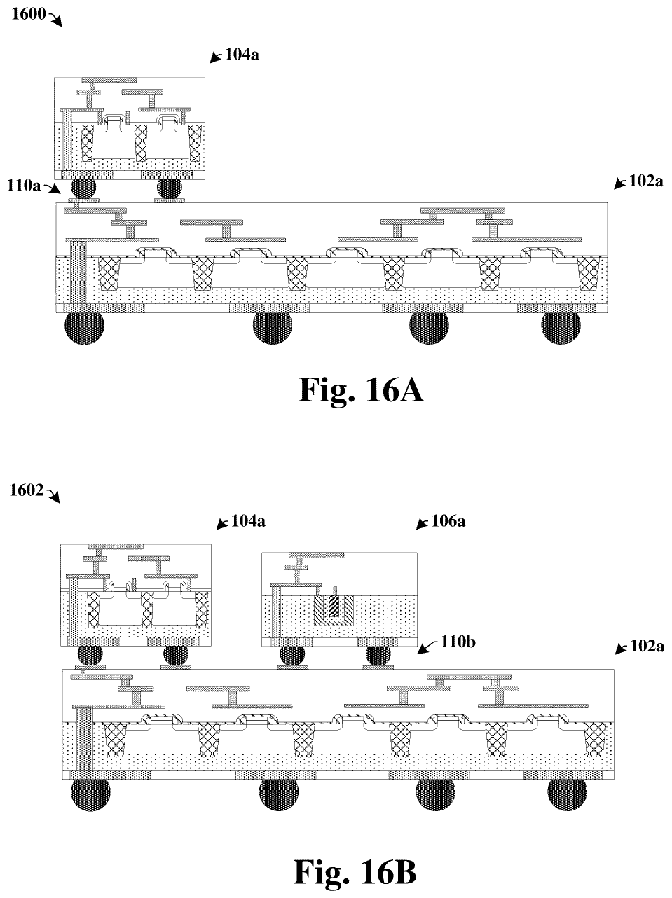

As shown in cross-sectional view 1500 of FIG. 15A, a fourth substrate 202d is provided. In various embodiments, the fourth substrate 202d may be any type of semiconductor body (e.g., silicon, SiGe, SOI, etc.), such as a semiconductor wafer and/or one or more die on a wafer, as well as any other type of semiconductor and/or epitaxial layers, associated therewith.

As shown in cross-sectional view 1502 of FIG. 15B, a third plurality of transistor devices 228 are formed on and/or within the fourth substrate 202d. The third plurality of transistor devices 228 may comprise a majority of the devices within the fourth substrate 202d. In some embodiments, the third plurality of transistor devices 228 may define one or more gate driver circuits. In some embodiments, the third plurality of transistor devices 228 may be formed to have a third gate structure with a third gate length 230 that is different than (e.g., larger than) the first gate length 214 and/or the second gate length 220. In some embodiments, the third gate structure 228g may comprise a third gate electrode 228e separated from the fourth substrate 202d by a third gate dielectric 228d. In some embodiments, the third gate structure 228g may be formed over a third well region 302d that is between one or more third isolation structures 304d.

As shown in cross-sectional view 1504 of FIG. 15C, a fourth CESL 308d is formed on the fourth substrate 202d over the third plurality of transistor devices 228. The fourth CESL 308d may comprise a nitride (e.g., silicon nitride), a carbide (e.g., silicon carbide), or the like. A fourth plurality of interconnects 206d may be formed within a fourth ILD structure 204d formed on the fourth CESL 308d.

As shown in cross-sectional view 1506 of FIG. 15D, the fourth substrate 202d may be thinned to reduce a thickness of the fourth substrate 202d. In various embodiments, the fourth substrate 202d may be thinned by etching and/or mechanical grinding a back-side of the fourth substrate 202d to reduce the thickness of the fourth substrate 202d (e.g., from a first thickness in a range of between approximately 700 μm and approximately 800 μm to a second thickness in a range of between approximately 20 μm and approximately 80 μm).

As shown in cross-sectional view 1508 of FIG. 15E, a fourth TSV 214d is formed to extend through the fourth substrate 202d. A fourth back-side bonding structure 210d is formed along a back-side of the fourth substrate 202d. The fourth back-side bonding structure 210d may be formed on and/or within a fourth passivation structure 211d that is formed along the back-side of the fourth substrate 202d.

As shown in cross-sectional view 1510 of FIG. 15F, the fourth substrate 202d is singulated to form a plurality of fourth chiplets 108a-108b. In some embodiments, the fourth substrate 202d may be singulated by a dicing process that mounts the fourth substrate 202d onto a sticky surface of a piece of dicing tape 1212. A wafer saw then cuts the fourth substrate 202d along scribe lines 1512 to separate the fourth substrate 202d into the plurality of fourth chiplets 108a-108b.

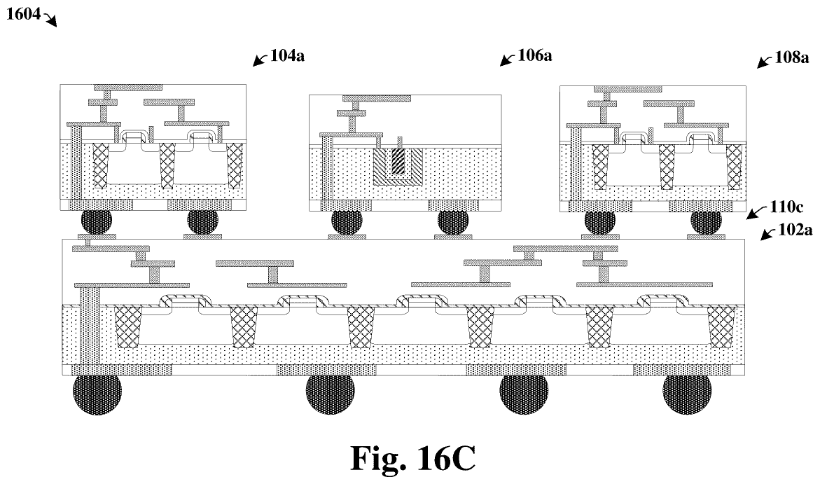

As shown in cross-sectional view 1600 of FIG. 16A, a first chiplet 102a of the plurality of first chiplets 102a-102b is coupled to a second chiplet 104a of the plurality of second chiplets 104a-104b. In some embodiments, the first chiplet 102a may be coupled to the second chiplet 104a by way of a first plurality of inter-chiplet connectors 110a. In some embodiments, the first plurality of inter-chiplet connectors 110a may comprise solder bumps, copper posts, micro-bumps (having widths in a range from about 5 μm to about 30 μm), or other applicable bump structures.

As shown in cross-sectional view 1602 of FIG. 16B, a third chiplet 106a of the plurality of third chiplets 106a-106b is coupled to the first chiplet 102a. In some embodiments, the third chiplet 106a may be coupled to the first chiplet 102a by way of a second plurality of inter-chiplet connectors 110b. In some embodiments, the second plurality of inter-chiplet connectors 110b may comprise solder bumps, copper posts, micro-bumps (having widths in a range from about 5 μm to about 30 μm), or other applicable bump structures.

As shown in cross-sectional view 1604 of FIG. 16C, a fourth chiplet 108a of the plurality of fourth chiplets 108a-108b is coupled to the first chiplet 102a. In some embodiments, the fourth chiplet 108a may be coupled to the first chiplet 102a by way of a third plurality of inter-chiplet connectors 110c. In some embodiments, third plurality of inter-chiplet connectors 110c may comprise solder bumps, copper posts, micro-bumps (having widths in a range from about 5 μm to about 30 μm), or other applicable bump structures.

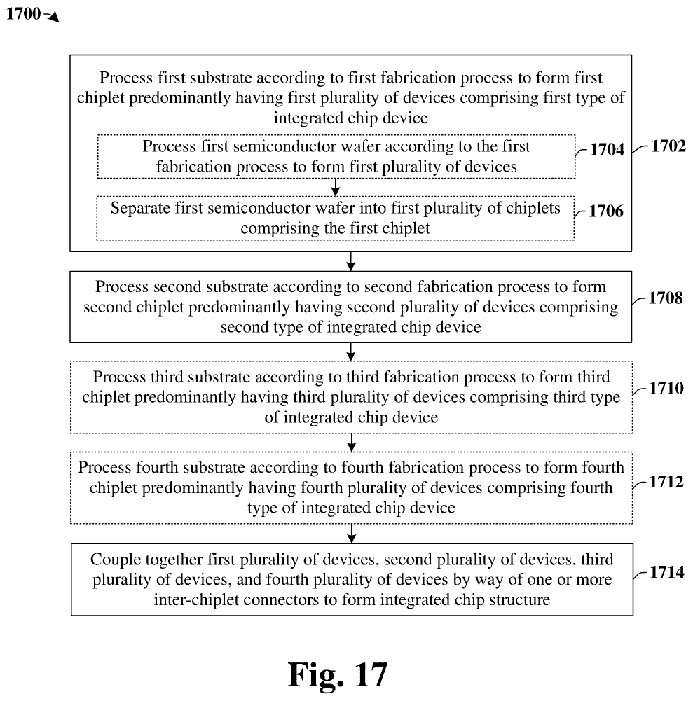

FIG. 17 illustrates a flow diagram of some embodiments of a method 1700 of forming an integrated chip structure comprising a plurality of chiplets respectively predominantly having a single type of integrated chip device.

While the disclosed method 1700 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 1702, a first substrate may be processed according to a first fabrication process to form a first chiplet predominantly having a first plurality of devices that are a first type of integrated chip device. In some embodiments, the first type of integrated chip device may be an NMOS transistor. In some embodiments, the first fabrication process may be a fabrication process associated with a first technology node (e.g., a 7 nm technology node). In some embodiments, the first fabrication process may be performed according to acts 1704-1706.

At act 1704, a first semiconductor wafer may be processed according to the first fabrication process to form the first plurality of devices. FIGS. 12A-12E illustrate cross-sectional views 1200-1208 of some embodiments corresponding to act 1704.

At act 1706, the first semiconductor wafer may be separated into a first plurality of chiplets comprising the first chiplet. FIG. 12F illustrates a cross-sectional view 1210 of some embodiments corresponding to act 1706.

At act 1708, a second substrate may be processed according to a second fabrication process to form a second chiplet predominantly having a second plurality of devices that are a second type of integrated chip device. In some embodiments, the second type of integrated chip device may be a PMOS transistor. In some embodiments, the second fabrication process may be a fabrication process associated with a second technology node (e.g., a 14 nm technology node). FIGS. 13A-13F illustrate cross-sectional views 1300-1310 of some embodiments corresponding to act 1708.

At act 1710, in some embodiments a third substrate may be processed according to a third fabrication process to form a third chiplet predominantly having a third plurality of devices that are a third type of integrated chip device. In some embodiments, the third type of integrated chip device may be a passive device (e.g., a capacitor, inductor, resistor, or the like). In some embodiments, the third fabrication process may be a fabrication process associated with a third technology node (e.g., a 45 nm technology node). FIGS. 14A-14F illustrate cross-sectional views 1400-1410 of some embodiments corresponding to act 1710.

At act 1712, in some embodiments a fourth substrate may be processed according to a fourth fabrication process to form a fourth chiplet predominantly having a fourth plurality of devices that are a fourth type of integrated chip device. In some embodiments, the fourth type of integrated chip device may be a gate driver circuit. In some embodiments, the fourth fabrication process may be a fabrication process associated with a fourth technology node (e.g., a 32 nm technology node). FIGS. 15A-15F illustrate cross-sectional views 1500-1510 of some embodiments corresponding to act 1712.

At act 1714, the first chiplet, the second chiplet, the third chiplet, and the fourth chiplet are coupled together by way of one or more inter-chiplet connectors to form an integrated chip structure. FIGS. 16A-16C illustrate cross-sectional views 1600-1604 of some embodiments corresponding to act 1714.

Accordingly, in some embodiments, the present disclosure relates to an integrated chip structure comprising a plurality of chiplets that respectively and predominantly comprise different types of integrated chip devices.

In some embodiments, the present disclosure relates to an integrated chip structure. The integrated chip structure includes a first chiplet predominantly having a first plurality of integrated chip devices coupled to a first plurality of interconnects over a first substrate, the first plurality of integrated chip devices being a first type of integrated chip device; a second chiplet predominantly having a second plurality of integrated chip devices coupled to a second plurality of interconnects over a second substrate, the second plurality of integrated chip devices being a second type of integrated chip device that is different than the first type of integrated chip device; one or more inter-chiplet connectors disposed between the first chiplet and the second chiplet and configured to electrically couple the first chiplet and the second chiplet; and the plurality of interconnects having a first minimum width that is different than a second minimum width of the second plurality of interconnects. In some embodiments, the first chiplet only includes the first type of integrated chip device. In some embodiments, the first chiplet is devoid of the second type of integrated chip device. In some embodiments, the first type of integrated chip device is an NMOS transistor and the second type of integrated chip device is a PMOS transistor. In some embodiments, the NMOS transistor includes a first gate structure having a first gate length and the PMOS transistor includes a second gate structure having a second gate length that is different than the first gate length. In some embodiments, the first plurality of interconnects include a first conductive contact having the first minimum width and the second plurality of interconnects include a second conductive contact having the second minimum width that is different than the first minimum width. In some embodiments, the integrated chip structure further includes a third chiplet predominantly having a third plurality of integrated chip devices that are a third type of integrated chip device that is different than the first type of integrated chip device and the second type of integrated chip device; and a fourth chiplet predominantly having a fourth plurality of integrated chip devices that are a fourth type of integrated chip device that is different than the first type of integrated chip device, the second type of integrated chip device, and the third type of integrated chip device. In some embodiments, the third chiplet is devoid of transistor devices. In some embodiments, the third type of integrated chip device is a passive device and the fourth type of integrated chip device is a gate driver circuit.

In other embodiments, the present disclosure relates to an integrated chip structure. The integrated chip structure includes a first chiplet predominantly having NMOS transistors disposed on or within a first substrate, the NMOS transistors including a first gate structure having a first gate length and being disposed between first source/drain regions having a first doping type; a second chiplet predominantly having PMOS transistors disposed on or within a second substrate, the PMOS transistors including a second gate structure having a second gate length that is different than the first gate length, the second gate structure being disposed between second source/drain regions having a second doping type different than the first doping type; and one or more inter-chiplet connectors arranged between the first chiplet and the second chiplet, wherein the one or more inter-chiplet connectors are configured to electrically couple the NMOS transistors and the PMOS transistors. In some embodiments, the integrated chip structure further includes a first plurality of conductive contacts physically contacting the NMOS transistors and having a bottom surface with a first width; and a second plurality of conductive contacts physically contacting the PMOS transistors and having a bottom surface with a second width that is different than the first width. In some embodiments, the second gate length is larger than the first gate length. In some embodiments, the integrated chip structure further includes a third chiplet predominantly having passive devices disposed on or within a third substrate; and a fourth chiplet predominantly having one or more gate driver circuits disposed on or within a fourth substrate. In some embodiments, the first chiplet is larger than the second chiplet, the third chiplet, and the fourth chiplet. In some embodiments, the second chiplet, the third chiplet, and the fourth chiplet are disposed on an upper surface of the first chiplet. In some embodiments, the integrated chip structure further includes a first contact etch stop layer disposed on the first substrate and having a first type of strain; and a second contact etch stop layer disposed on the second substrate and having a second type of strain that is different than the first type of strain. In some embodiments, the integrated chip structure further includes a first sidewall spacer disposed along opposing sides of the first gate structure and having a first type of strain; and a second sidewall spacer disposed along opposing sides of the second gate structure and having a second type of strain that is different than the first type of strain. In some embodiments, a first channel region extending below the first gate structure extends along a first direction along a first crystal plane; and a second channel region extending below the first gate structure extends along a second direction along a second crystal plane, the second direction being different than the first direction.

In yet other embodiments, the present disclosure relates to a method for forming an integrated chip structure. The method includes processing a first substrate according to a first fabrication process to form a first chiplet predominantly having a first plurality of devices, the first plurality of devices are a first type of integrated chip device; processing a second substrate according to a second fabrication process to form a second chiplet predominantly having a second plurality of devices, the second plurality of devices are a second type of integrated chip device that is different than the first type of integrated chip device; and electrically coupling the first plurality of devices within the first chiplet to the second plurality of devices within the second chiplet by way of one or more inter-tier connectors. In some embodiments, the method the first type of integrated chip device is an NMOS transistor; and the second type of integrated chip device is a PMOS transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated chip structure, comprising:
a first chiplet predominantly comprising a first plurality of integrated chip devices coupled to a first plurality of interconnects over a first substrate, the first plurality of integrated chip devices being a first type of integrated chip device;
a second chiplet predominantly comprising a second plurality of integrated chip devices coupled to a second plurality of interconnects over a second substrate, the second plurality of integrated chip devices being a second type of integrated chip device that is different than the first type of integrated chip device;
one or more inter-chiplet connectors disposed between the first chiplet and the second chiplet and configured to electrically couple the first chiplet and the second chiplet; and
wherein the first plurality of interconnects have a first minimum width that is different than a second minimum width of the second plurality of interconnects.

2. The integrated chip structure of claim 1, wherein the first chiplet only comprises the first type of integrated chip device.

3. The integrated chip structure of claim 1, wherein the first chiplet is devoid of the second type of integrated chip device.

4. The integrated chip structure of claim 1,
wherein the first type of integrated chip device is an NMOS transistor; and
wherein the second type of integrated chip device is a PMOS transistor.

5. The integrated chip structure of claim 4, wherein the NMOS transistor comprises a first gate structure having first gate length and the PMOS transistor comprises a second gate structure having a second gate length that is different than the first gate length.

6. The integrated chip structure of claim 1, wherein the first plurality of interconnects comprise a first conductive contact having the first minimum width and the second plurality of interconnects comprise a second conductive contact having the second minimum width that is different than the first minimum width.

7. The integrated chip structure of claim 1, further comprising:
a third chiplet predominantly comprising a third plurality of integrated chip devices that are a third type of integrated chip device that is different than the first type of integrated chip device and the second type of integrated chip device; and
a fourth chiplet predominantly comprising a fourth plurality of integrated chip devices that are a fourth type of integrated chip device that is different than the first type of integrated chip device, the second type of integrated chip device, and the third type of integrated chip device.

8. The integrated chip structure of claim 7, wherein the third chiplet is devoid of transistor devices.

9. The integrated chip structure of claim 8,
wherein the third type of integrated chip device is a passive device; and
wherein the fourth type of integrated chip device is a gate driver circuit.

10. An integrated chip structure, comprising:
a first chiplet predominantly comprising NMOS transistors disposed on or within a first substrate, wherein the NMOS transistors comprise a first gate structure having a first gate length and being disposed between first source/drain regions having a first doping type;
a second chiplet predominantly comprising PMOS transistors disposed on or within a second substrate, wherein the PMOS transistors comprise a second gate structure having a second gate length that is different than the first gate length, the second gate structure being disposed between second source/drain regions having a second doping type different than the first doping type; and
one or more inter-chiplet connectors arranged between the first chiplet and the second chiplet, wherein the one or more inter-chiplet connectors are configured to electrically couple the NMOS transistors and the PMOS transistors.

11. The integrated chip structure of claim 10, further comprising:
a first plurality of conductive contacts physically contacting the NMOS transistors and having a bottom surface with a first width; and
a second plurality of conductive contacts physically contacting the PMOS transistors and having a bottom surface with a second width that is different than the first width.

12. The integrated chip structure of claim 10, wherein the second gate length is larger than the first gate length.

13. The integrated chip structure of claim 10, further comprising:
a third chiplet predominantly comprising passive devices disposed on or within a third substrate; and
a fourth chiplet predominantly comprising one or more gate driver circuits disposed on or within a fourth substrate.

14. The integrated chip structure of claim 13, wherein the first chiplet is larger than the second chiplet, the third chiplet, and the fourth chiplet.

15. The integrated chip structure of claim 13, wherein the second chiplet, the third chiplet, and the fourth chiplet are disposed on an upper surface of the first chiplet.

16. The integrated chip structure of claim 10, further comprising:
a first contact etch stop layer disposed on the first substrate and having a first type of strain; and
a second contact etch stop layer disposed on the second substrate and having a second type of strain that is different than the first type of strain.

17. The integrated chip structure of claim 10, further comprising:
a first sidewall spacer disposed along opposing sides of the first gate structure and having a first type of strain; and
a second sidewall spacer disposed along opposing sides of the second gate structure and having a second type of strain that is different than the first type of strain.

18. The integrated chip structure of claim 10,
wherein a first channel region extending below the first gate structure extends along a first direction along a first crystal plane; and
wherein a second channel region extending below the first gate structure extends along a second direction along a second crystal plane, the second direction being different than the first direction.

19-20. (canceled)

21. An integrated chip structure, comprising:
a first chiplet associated with a first technology node having a first minimum feature size and predominantly comprising a first plurality of integrated chip devices coupled to a first plurality of interconnects over a first substrate, the first plurality of integrated chip devices being a first type of integrated chip device;
a second chiplet associated with a second technology node having a second minimum feature size that is different than the first minimum feature size, the second chiplet predominantly comprising a second plurality of integrated chip devices coupled to a second plurality of interconnects over a second substrate, the second plurality of integrated chip devices being a second type of integrated chip device that is different than the first type of integrated chip device;
a third chiplet predominantly comprising a third type of integrated chip device that is different than the first type of integrated chip device and the second type of integrated chip device; and
a plurality of conductive bump structures disposed between an upper surface of the first chiplet and lower surfaces of the second chiplet and the third chiplet.

22. The integrated chip structure of claim 21, wherein the second chiplet has a first height and the third chiplet has a second height that is different than the first height.
